(19) United States
(12) Patent Application Publication
(10) Pub. No.: US 2026/0303020 A1
(43) Pub. Date: Oct. 1, 2026

(54) SYSTEM AND METHOD FOR THz AMPLIFICATION BY WAVELENGTH INJECTION OF RESONANT TUNNELING DIODE OSCILLATOR

(71) Applicant: IMRA America, Inc., Ann Arbor, MI (US)

(72) Inventors: James Greenberg, Boulder, CO (US); Antoine Jean Gilbert Rolland, Denver, CO (US); William Francis McGrew, Boulder, CO (US); Brendan Michael Heffernan, Boulder, CO (US)

(21) Appl. No.: 19/574,186

(22) Filed: Mar. 20, 2026

Related U.S. Application Data
(60) Provisional application No. 63/779,637, filed on Mar. 28, 2025.

(51) Int. Cl. H03B 7/08; G02B 6/293; H03B 1/04

(52) U.S. Cl. CPC H03B 7/08; G02B 6/29353; H03B 1/04; H03B 2200/0044; H03B 2200/007; H03B 2200/0074; H03B 2200/0084

(57) ABSTRACT

A device includes a waveguide resonant tunneling diode (RTD) configured to oscillate at a terahertz (THz) frequency, a DC power supply electrically coupled to the RTD and configured to provide a DC bias voltage to the RTD, and a waveguide isolating element operatively connected to the RTD. The RTD, when injection-locked to an external incident radiation signal having a first frequency, generates and emits an output radiation signal having a second frequency

### CLAIM OF PRIORITY

This application claims the benefit of priority to U.S. Provisional Appl. No. 63/779,637 filed Mar. 28, 2025 and incorporated in its entirety by reference herein.

### BACKGROUND

### Field

The present application relates generally to an amplification device of terahertz radiation (e.g., 100 GHz to 10 THz).

### Description of the Related Art

Resonant tunneling diodes (RTDs) have been developed and demonstrated as low-cost and energy efficient means of generating terahertz frequency radiation (e.g., 100 GHz to 10 THz). See, e.g., M. Asada and S. Suzuki, J Infrared Milli Terahz Waves, vol. 37, no. 12, pp. 1185-1198, December 2016; U.S. Pat. Nos. 10,205,242B2; 8,436,382B2. One realm of applications for such devices is in next generation wireless communications: characterized by THz carrier frequencies. (see, e.g., T. Schneider et al., IEEE Transactions on Terahertz Science and Technology, vol. 2, no. 2, pp. 250-256, 2012). RTDs have demonstrated both the tuning range and output power utilized for such applications. A challenge that remains, however, is the spectral purity of the THz radiation. The quality of this radiation, as characterized by amplitude and phase noise, directly impacts the amount of data that can be encoded, transmitted, carried, demodulated, and eventually detected wirelessly. Furthermore, frequency drift of these devices affects the channelization of future wireless communication schemes.

One candidate for such high purity radiation is photomixed optical sources which have demonstrated state-of-the-art spectral purity and tunability. Such optical sources have also been used directly for 300 GHz wireless communications demonstrations. However, the photomixing technology can dramatically lose power as the frequency of the carrier increases above 300 GHz. This challenge can be overcome by amplification. However, commercially available amplifiers have a maximum frequency of about 300 GHz and a maximum gain of only 25 dB.

Injection of low power, high quality radiation can greatly improve the spectral purity of any oscillator (see, e.g., R. Adler, Proceedings of the IEEE, vol. 61, no. 10, pp. 1380-1385, 1973). In the case of an RTD, injection can also lock the frequency to a microwave reference and effectively mitigate drift which has been demonstrated utilizing a photomixed source of THz radiation and free-space isolators and the reflection geometry of injection (see, e.g., T. Hiraoka et al., APL Photonics, vol. 6, no. 2, p. 021301, February 2021). The spectral purity was dramatically enhanced, but the free-space isolators led to enormous power loss. So much so, that the direct output of the photomixer was larger than the resulting injected radiation.

Another injection demonstration with RTDs showed they can act as harmonic frequency multipliers (see, e.g., K. Arzi et al., IEEE Transactions on Terahertz Science and Technology, vol. 10, no. 2, pp. 221-224, 2020) in which an amplifier, multiplier chain (AMC) was used as the external source of THz radiation and a transmission injection geometry was utilized. Again, the resulting power of the multiplied radiation was lower than achievable via direct generation of the AMC. Additionally, both injection demonstrations suffered from free-space alignment of all the components involved. Free-space configurations can lead to a lack of robustness desired for a widely deployed commercial application.

Free-space power losses can be mitigated utilizing waveguide components. RTDs have been mounted in waveguide packaging for several practical demonstrations including as THz detectors (see, e.g., Y. Takida et al., Applied Physics Letters, vol. 117, no. 2, p. 021107, 2020), communications (see, e.g., X. Yu et al., Electronics Letters, vol. 56, no. 7, pp. 342-344, 2020), and imaging (see, e.g., J. Wang et al. Applied Sciences, vol. 12, no. 8, Art. no. 8, 2022). None of these waveguide RTD demonstrations so far achieved spectral purification via injection from an external source of THz radiation.

Mutual injection of RTD arrays have also been shown (see, e.g., Y. Koyama et al., IEEE Trans. THz Sci. Technol., vol. 12, no. 5, pp. 510-519, 2022) which reduced phase noise by a factor of sqrt(N), where N is the number of RTD elements. Mutual injection can also increase the output power of the device. These devices can also stand to benefit from external injection of THz radiation as the mutual injection reduces the power from an external source for synchronizing the collective oscillation.

An alternative method to reduce the phase noise of an RTD is by phase locking directly to a microwave reference which can utilize a fast cavity tuning element, such as a varactor diode mounted in the slot antenna. A study successfully employed this method to dramatically reduce the phase noise of an RTD. (see, e.g., K. Ogino, S. Suzuki, and M. Asada, J Infrared Milli Terahz Waves, vol. 38, no. 12, pp. 1477-1486, 2017). A phase-locked loop (PLL), however, is inherently bandwidth limited by the loop filter (e.g., electronics) employed. External injection locking can achieve a much greater bandwidth than a PLL, without any external electronics. This attribute can be especially important in the context of wireless communications, because wireless signals are typically encoded (e.g., modulated) far from the carrier. Thus, a PLL with insufficient speed will erase any data encoded on the noise mitigated THz radiation.

### SUMMARY

In certain implementations, a device comprises a waveguide resonant tunneling diode (RTD) configured to oscillate at a terahertz (THz) frequency, a DC power supply electrically coupled to the RTD and configured to provide a DC bias voltage to the RTD, and a waveguide isolating element operatively connected to the RTD. The RTD, when injection-locked to an external incident radiation signal having a first frequency, generates and emits an output radiation signal having a second frequency.

In certain implementations, a method is provided for injection locking a waveguide RTD and characterizing absolute phase noise of the resulting THz radiation. The method comprises injecting a waveguide RTD with a first reference THz radiation signal. The method further comprises applying a DC bias voltage to the RTD to tune an oscillation frequency of the RTD and to establish injection locking with the first reference THz signal. The method further comprises mixing an amplified RTD output signal from the RTD with a second THz reference signal to form an intermediate frequency (IF) output signal in response to a mixture of the amplified RTD output signal and the second THz reference signal. The method further comprises measuring an absolute phase noise of the first reference THz radiation signal.

In certain implementations, a method is provided for injection locking a waveguide RTD and characterizing residual phase noise of the waveguide RTD. The method comprises generating a THz reference signal and splitting the THz reference signal into a first portion and a second portion. The method further comprises applying a frequency shift to the second portion using a frequency synthesizer. The method further comprises injecting a waveguide RTD with the first portion of the THz reference signal. The method further comprises mixing an amplified RTD output signal from the waveguide RTD with the frequency-shifted second portion in a waveguide mixer. The method further comprises analyzing a resulting IF signal from the waveguide mixer using a phase noise analyzer synchronized to the frequency synthesizer to determine a residual phase noise introduced by injecting the waveguide RTD with the first portion of the THz reference signal.

### BRIEF DESCRIPTION OF THE DRAWINGS

FIG. 1A is a schematic of an example device (e.g., injection amplifier) utilizing the reflection geometry in accordance with certain implementations described herein.

FIG. 1B is a schematic of an example device (e.g., injection amplifier) utilizing the transmission geometry in accordance with certain implementations described herein.

FIG. 2A is a schematic of an example device (e.g., injection multiplier) utilizing the reflection geometry in accordance with certain implementations described herein.

FIG. 2B is a schematic of an example device (e.g., injection multiplier) utilizing the transmission geometry in accordance with certain implementations described herein.

FIG. 3A is a schematic of an example device (e.g., tracking oscillator) utilizing the reflection geometry in accordance with certain implementations described herein.

FIG. 3B is a schematic of an example device (e.g., tracking oscillator) utilizing the transmission geometry in accordance with certain implementations described herein.

FIGS. 4A and 4B is a schematic of an example wireless communication system utilizing an example device (e.g., THz repeater) in accordance with certain implementations described herein.

FIG. 5 is a schematic of an example device (e.g., subharmonic mixer) in accordance with certain implementations described herein.

FIG. 6 is a schematic of an example system (e.g., demultiplexing system) within the context of a multiplexed wireless communications system in accordance with certain implementations described herein.

FIG. 7 is a schematic of an example system (e.g., photomixer multiplexer) in accordance with certain implementations described herein.

FIG. 8 is a schematic of an example system (e.g., comprising a wireless link) in accordance with certain implementations described herein.

FIG. 9A is a schematic of an example system (e.g., utilizing absolute injection PN) in accordance with certain implementations described herein.

FIG. 9B is a flow diagram of an example method in accordance with certain implementations described herein.

FIG. 9C is a plot of the phase noise power spectral densities (PSD) for a free running RTD (top trace), a dual wavelength Brillouin laser (DWBL) (bottom trace), and injected RTD and several injection powers for an example system in accordance with FIG. 9A.

FIG. 9D is a plot of the variation of RTD injection locking frequency range with injection power ratio for an example system in accordance with FIG. 9A.

FIG. 10A is a schematic of an example system (e.g., utilizing residual injection PN) in accordance with certain implementations described herein.

FIG. 10B is a flow diagram of an example method in accordance with certain implementations described herein.

FIGS. 11A and 11B schematically illustrate an example device (e.g., a high-speed, voltage-controlled phase modulator) in accordance with certain implementations described herein.

FIGS. 12A and 12B schematically illustrate an example device (e.g., a high-speed, voltage-controlled intensity modulator) in accordance with certain implementations described herein.

### DETAILED DESCRIPTION

Certain implementations described herein include the amplification of THz radiation via injection of external THz radiation into a waveguide RTD. The external THz radiation can be incident upon a waveguide RTD and the waveguide RTD can be tuned by a DC bias voltage to oscillate at the incident frequency. When the frequency is tuned, injection locking can occur and the RTD can synchronize with the incident radiation. The radiation from the RTD can then be an amplified copy of the incident radiation. The bandwidth of the injection lock, and thus the bandwidth of the amplifier, can be described by injection locking theory: namely, by the ratio of incident, external radiation power to the power emitted by the waveguide RTD. A waveguide isolating element, such as a circulator or isolator, can be utilized to prevent the formation of external cavities with the RTD, thus ensuring synchronization between the incident radiation and the RTD oscillation. Using only waveguide components can reduce (e.g., minimize) power losses and can improve robustness to the point where a practical communications system can be realized.

Injection locking of an RTD to an external THz source can be realized in two geometries. A reflection geometry (e.g., utilizing a waveguide circulator) and a transmission geometry (e.g., utilizing only an isolator). Both geometries are compatible with waveguide RTDs and can result in a functional amplifier.

For the reflection geometry, a weak THz signal can be incident upon the input (e.g., port 1) of a 3-port waveguide circulator. A waveguide RTD can be fixed to port 2 of the circulator, and the RTD can be biased by a DC supply. The voltage from the DC supply can be varied such that the RTD oscillates at a frequency very near the input THz signal frequency. When tuned, the RTD can synchronize with the input radiation and can be injection locked. The output of the circulator (e.g., port 3) can be the injected RTD with more power than incident on the input. Thus, amplification of the input signal can be achieved, through injection locking of the waveguide RTD.

For the transmission geometry, a weak THz signal can be incident upon the back facet of a waveguide RTD and the RTD can be biased by a DC supply. The voltage from the DC supply can be varied such that the RTD oscillates at a frequency very near the input THz signal frequency. When tuned, the RTD can synchronize with the input radiation that transmits through the back facet of the RTD and the RTD can become injection locked. The output of the waveguide RTD can transmit through a waveguide isolator. The output of the waveguide isolator can be the injected RTD with more power than incident on the input. Thus, amplification of the input signal can be achieved, through injection locking of the waveguide RTD.

In both the reflection and transmission geometries, an isolating component can be the final element before the output, which can prevent reflected radiation from entering the amplifier which could disrupt the synchronization of a weak incident signal and RTD.

### Various Example Implementations

The various example THz devices and derivatives described herein are illustrative, not restrictive. A variety of alternative implementations, working examples, and operational techniques are also compatible with certain implementations described herein.

### Example 1: Waveguide RTD Injection Amplifier

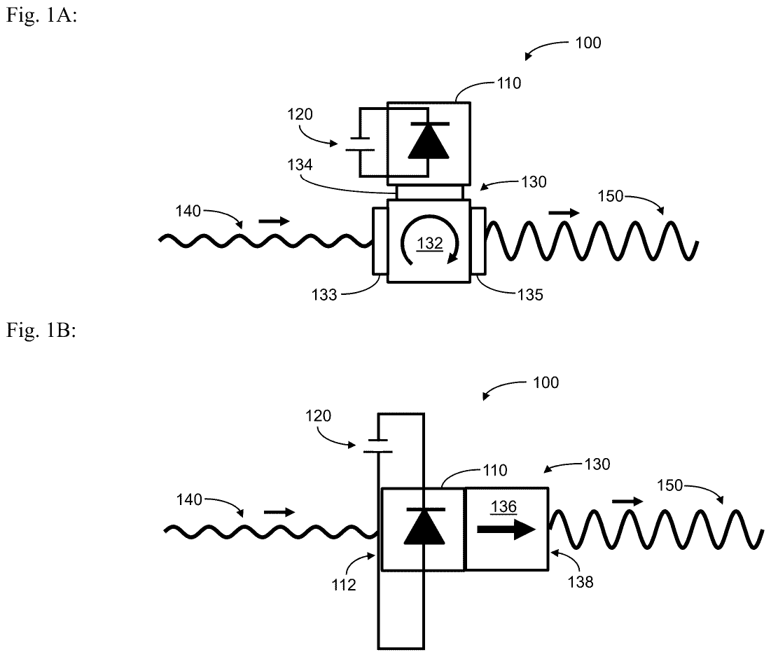

FIGS. 1A and 1B schematically illustrate an example device 100 (e.g., waveguide RTD injection amplifier) in accordance with certain implementations described herein. In FIG. 1A, the example device 100 has a reflection geometry and in FIG. 1B, the example device 100 has a transmission geometry. The example device 100 comprises a waveguide resonant tunneling diode (RTD) 110 configured to oscillate at a terahertz (THz) frequency, a DC power supply 120 electrically coupled to the RTD 110 and configured to provide a DC bias voltage to the RTD 110. The device 100 further comprises a waveguide isolating element 130 (e.g., a circulator 132 in FIG. 1A; an isolator 136 in FIG. 1B) operatively connected to the RTD 110. The RTD 110, when injection-locked to an external incident radiation signal 140 having a first frequency, generates and emits an output radiation signal 150 having a second frequency. As described herein with regard to FIGS. 1A and 1B, the device 100 can operate as an injection amplifier (e.g., the first frequency of the external incident radiation signal 140 can be a THz frequency, the second frequency of the output radiation signal 150 can be substantially equal to the first frequency, and the output radiation signal 150 can be amplified compared to the external incident radiation signal 140).

As shown in FIG. 1A, the waveguide isolating element 130 comprises a three-port waveguide circulator 132 having a first port 133 (e.g., input port) configured to receive the external incident radiation signal 140, a second port 134 (e.g., first output port) in optical communication with the RTD 110, and a third port 135 (e.g., second output port) configured to emit the output radiation signal 150. As shown in FIG. 1B, the waveguide isolating element 130 comprises an optical isolator 136, the RTD 110 comprises an input port 112 (e.g., input port of the device 100) configured to receive the external incident radiation signal 140 and an output port 114 in optical communication with the optical isolator 136. The RTD 110 can be configured (e.g., mounted into a waveguide package) such that radiation (e.g., waveguided radiation) from both the input port 112 and the output port 114 interact with an oscillating portion of the RTD 110. The optical isolator 136 can comprise an input port 137 in optical communication with the output port 114 of the RTD 110 and an output port 138 (e.g., output port of the device 100) configured to emit the output radiation signal 150.

In the example device 100 of FIG. 1A and FIG. 1B, the bias voltage of the DC power supply 120 can tune the frequency of the output radiation signal 150 emitted by the device 100. When the frequency is tuned to within an injection locking bandwidth of the incident radiation signal 140, injection locking can occur. The emitted output radiation signal 150 can be an amplified copy of the incident radiation signal 140 (e.g., the output radiation signal 150 is amplified compared to the external incident radiation signal 140), within the bandwidth of the injection locking. In certain implementations, the waveguide isolating element 130 (e.g., circulator 133; optical isolator 136) can prevent radiation incident upon the output of the device 100 (e.g., third port 135 in FIG. 1A; output port 138 in FIG. 1B) from interfering with the injection process, thereby providing a stable injection-based amplifier (e.g., in the reflection geometry of FIG. 1A; in the transmission geometry of FIG. 1B) using a waveguide RTD 110.

In certain other examples described herein, the device 100 (e.g., injection amplifier), in either the reflection geometry (e.g., FIG. 1A) or the transmission geometry (e.g., FIG. 1B), serves as a basic building block. Both geometries are functionally equivalent and can be seen as interchangeable.

In certain implementations, the injection locking range of the RTD 110 is a function of the power ratio of the incident power to emitted power. The effective bandwidth of the device 100 can be estimated by this locking range. For example, utilizing a 260 GHz wave, a 1 GHz bandwidth results from a power ratio of 0.1. The inverse power ratio can also be a measure of the amplification factor. Without active tuning of the RTD bias voltage, 40 dB amplification can accompany a 10 MHz bandwidth. Active tracking methods for the RTD bias voltage can allow for an even greater amplification ratio, and narrower bandwidth.

In certain implementations, utilizing an array of devices 100 (e.g., in a waveguide) can effectively increase the quality factor of the RTD 110. The impact on injection can be an enhanced amplification factor and narrower locking range/bandwidth.

### Example 2: Waveguide RTD Injection Frequency Multiplier

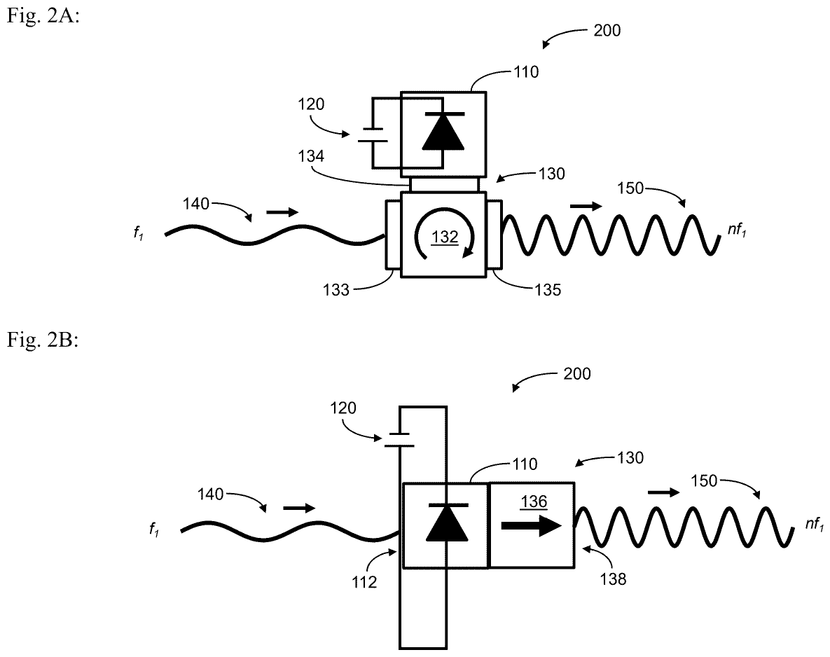

FIGS. 2A and 2B schematically illustrate another example device 200 (e.g., amplifying frequency multiplier) in accordance with certain implementations described herein. The example device 200 of FIG. 2A has the same components as does the example device 100 of FIG. 1A, arranged in a reflection geometry, and the example device 200 of FIG. 2B has the same components as does the example device 100 of FIG. 1B, arranged in a transmission geometry. The difference between the example device 100 of FIGS. 1A and 1B and the example device 200 of FIGS. 2A and 2B is that the RTD 110 of FIGS. 2A and 2B is tuned to a harmonic multiple of the first frequency of the external incident radiation signal 140. When tuned within the injection locking range, harmonic injection can occur, which can result in the synchronization of the external incident radiation signal 140 and the output radiation signal 150 radiated by the RTD 110 at a second frequency that is an integer multiple of the first frequency. For example, an external source of THz radiation can be frequency multiplied and radiated from the output, such that the device 200 operates as a THz harmonic frequency multiplier device.

In certain implementations of the example device 200 of FIGS. 2A and 2B, the RTD 110 is mounted in a waveguide package (not shown), the package comprising an input port and an output port. The sizes of the waveguides in the components of FIGS. 2A and 2B can be matched to the expected range of frequencies on both the input and output ports. Smaller waveguides can be better for higher frequencies, leading to an improvement of the multiplier performance, in terms of power loss and conversion efficiency. The input port can have a waveguide dimension larger than that of the output port, such that the package is configured to accommodate a higher input frequency and to facilitate harmonic locking. In certain implementations, in the example device 200 of FIGS. 2A and 2B, filtering of the external incident radiation signal can also be achieved by the waveguide of the output port and the waveguide isolating element 130 (e.g., circulator 132; optical isolator 136) can only isolate radiation at the designed harmonic multiple frequency. Because higher frequencies propagate in larger waveguides, this matching of waveguide sizes is not required. A larger bandwidth of the waveguide isolating element 130 can be used if the waveguide size matching is omitted, to provide isolation at the input and output frequencies.

### Example 3: Waveguide RTD Injection Tracking Oscillator

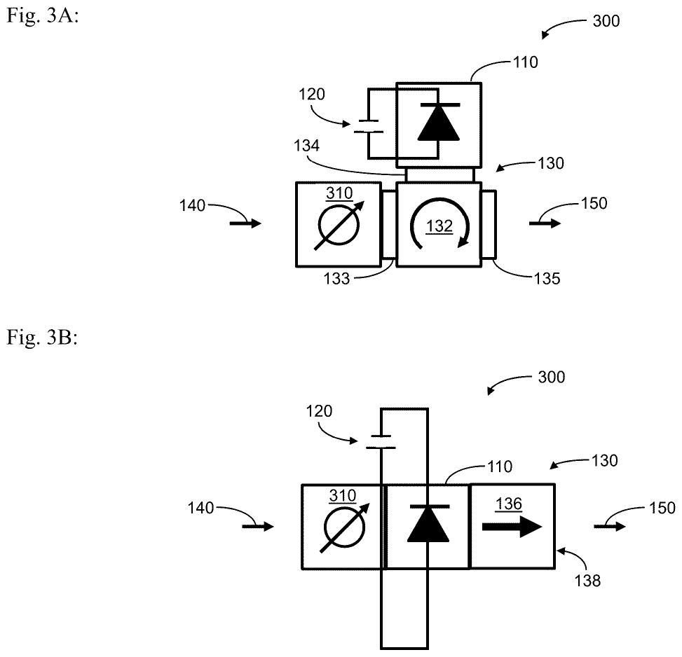

The example device 100 schematically illustrated by FIGS. 1A and 1B can be a component of tracking oscillators since the device 100 will follow any frequency drifts of the external incident radiation signal 140, provided the drifts stay within the bandwidth of the injection lock. Another feature of a tracking oscillator is tuning of the tracking bandwidth. In the example device 100 of FIGS. 1A and 1B, the power ratio tunes the injection amplification locking range, and thus amplifier bandwidth. FIGS. 3A and 3B schematically illustrate another example device 300 (with reflection and transmission geometry, respectively), the device 300 further comprising a variable THz power attenuator 310 in accordance with certain implementations described herein. The power attenuator 310 can be configured to control an amplitude of the external incident radiation signal 140. Examples of the power attenuator 310 include but are not limited to: manually tunable power attenuators; voltage-tunable power attenuators; power attenuators available from Eravant of Torrance CA. A tracking bandwidth of the RTD 110 can be determined by a ratio of input power of the external incident radiation signal 140 to an oscillation power of the RTD 110, enabling frequency tracking within an injection locking frequency range. In FIG. 3A, the power attenuator 310 is in optical communication with the first port 133 of the circulator 132 and the power attenuator 310 is in optical communication with the input port 112 of the RTD 110.

The device 300 (e.g., tracking oscillator based on waveguide RTD injection) can also be a tunable, amplifying THz filter. The center frequency can be tuned by the DC bias voltage on the RTD 110, while the filter bandwidth can be tuned by the variable power attenuator 310. An extremely wide range of bandwidths can be achievable (e.g., less than 10 MHz to greater than 1 GHz), as well as a range of central frequencies spanning the THz band.

### Example 4: Waveguide RTD Injection Wireless Repeater

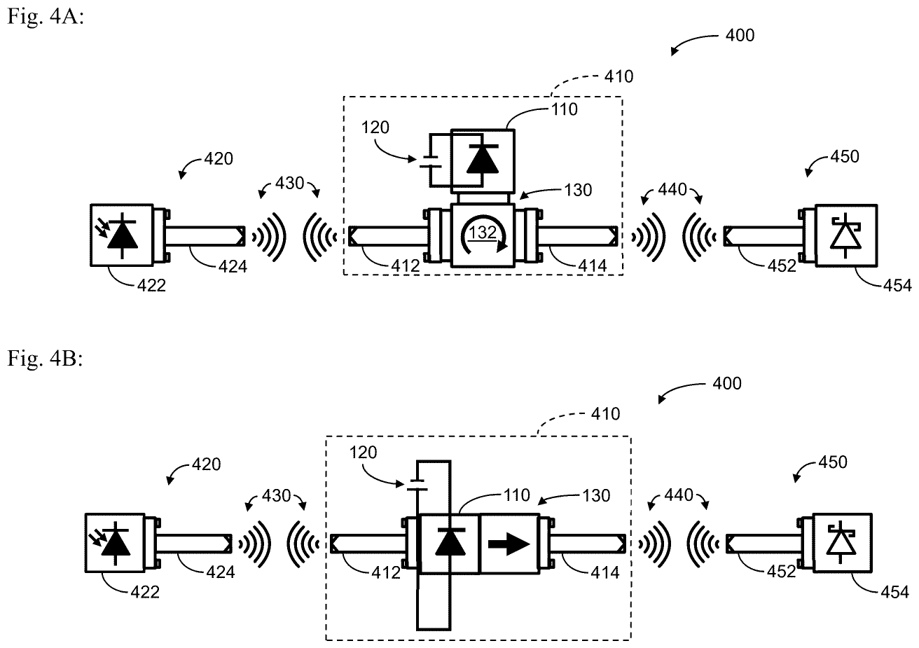

In certain implementations, a wireless communication system 400 utilizing the device 100 can balance a desired data transmission rate, link directivity, and link distance. FIGS. 4A and 4B schematically illustrate an example wireless communication system 400 in accordance with certain implementations described herein. Operating at THz carrier frequencies can present an additional challenge of atmospheric absorption which can limit the practical link range and data rates for various bands of THz wireless communications. Wireless repeaters are devices that act as intermediate receiver stations that extend the overall distance of a wireless transmission. The example system 400 of FIGS. 4A and 4B comprises an example wireless repeater 410 (e.g., THz injection wireless repeater) within the context of a representative THz wireless communications link in accordance with certain implementations described herein. A THz transmitter 420 (e.g., wireless transmitter) can comprise a THz emitter 422 and a first antenna/feedhorn 422 configured to radiate a first THz wave 430 carrying encoded data over free-space. The example wireless repeater 410 can further comprise a second antennae/feedhorn 412 configured to receive at least a portion of the THz wave 430 (e.g., input; external incident radiation signal 140) and to allow the received portion to propagate via a waveguide to the waveguide isolating element 130 (e.g., circulator 132 of FIG. 4A; optical isolator 136 of FIG. 4B) and a third antennae/feedhorn 414 configured to receive the output radiation signal 150 from the waveguide isolating element 130 and to emit the output radiation signal 150 as a second THz wave 440 (e.g., amplified THz wave) with the encoded information. The example system 400 can further comprise a THz receiver 450 (e.g., THz wireless receiver) comprising a fourth antennae/feedhorn 452 configured to receive at least a portion of the second THz wave 440 and to allow the received portion to propagate via a waveguide to a THz detector 454. Utilizing the device 100 (e.g., injection waveguide RTD amplifier) of FIGS. 1A and 1B in either reflection geometry (FIG. 4A) or transmission geometry (FIG. 4B), the example wireless repeater 410 of FIGS. 4A and 4B can radiate the amplified THz wave with the encoded information to the THz wireless receiver 450.

In certain implementations the wireless repeater 410 can have a sufficiently large (e.g., 40 dB) amplification ratio configured to combat the challenge of atmospheric absorption for THz wireless communications systems. In contrast, commercially available waveguide amplifiers around 260 GHz can provide around 25 dB of gain.

In certain implementations, the wireless repeater 410 is configured for other kinds of THz wireless links besides communications. For example, THz signals derived from optical atomic clocks can be used to wirelessly synchronize locations to the world's most accurate frequency standards. The example wireless repeater 410 (e.g., waveguide RTD injection repeater) of FIGS. 4A and 4B can be configured to boost power and thus link distance of such a wireless clock signal.

In certain implementations, the wireless repeater 410 is configured for radioastronomy. Very tiny signals from the far reaches of our universe can be detected over long periods of time by large THz arrays (e.g., such as the ALMA collaboration). The wireless repeater 410 of FIGS. 4A and 4B can be configured to boost interstellar signals resulting in a higher signal-to-noise ratio and thus less averaging time (e.g., observation time) to achieve the desired measurement precision.

### Example 5: Waveguide RTD Injection Subharmonic Mixer

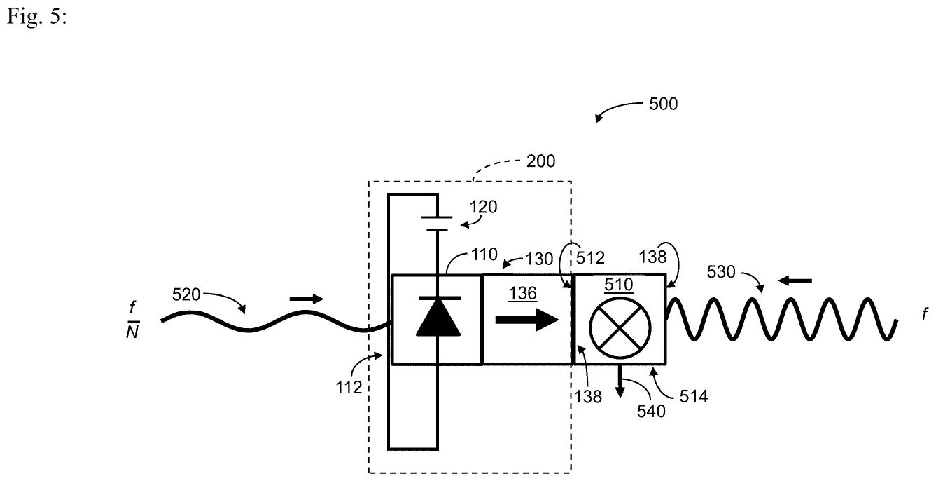

FIG. 5 schematically illustrates another example device 500 (e.g., THz subharmonic mixer) in accordance with certain implementations described herein. The example device 500 comprises a device 200 (e.g., a waveguide RTD injection multiplier) as schematically illustrated by FIG. 2B and a fundamental mixer 510 (e.g., subharmonic mixer). The LO input 520 of the example device 500 can connect to the input port 112 of the device 200 and the output port 138 of the device 200 can be in optical communication with a first input port 512 (e.g., LO port) of the mixer 510 and a second input port 514 (e.g., RF input port) can be configured to receive external THz radiation 530 (e.g., RF input) and to couple the external THz radiation 530 into the mixer 510. The mixer 510 can further comprise an output port 514 configured to emit a mixed signal 540 (e.g., intermediate frequency or IF) that is a mixture of the external THz radiation 530 received by the second input port 514 and a harmonic multiple of the LO input 520 received at the input port 112. In certain implementations, the RTD 110 is configured to generate a coherent reference signal local oscillator for phase-sensitive detection. The device 200 (e.g., frequency multiplier) can be a component of a subharmonic mixer. The coherence of the reference signal is not required to realize a subharmonic mixer. If the reference signal is coherent, however, the device 500 can become a phase-sensitive detector.

In certain implementations, injection multiplication can be significantly more power efficient than nonlinear generation of higher harmonics. Only one harmonic is produced, determined by the DC bias voltage 120 of the RTD 110. Harmonic injection can occur at large power ratios, so long as the resulting bandwidth is sufficient. As a result, the subharmonic mixer 500 of FIG. 5 can have significantly lower conversion loss than do THz subharmonic mixers relying on nonlinear harmonic generation.

While FIG. 5 schematically illustrates a device 500 having the transmission geometry, in certain other implementations, the device 500 can have the reflection geometry.

### Example 6: THz Wireless Communications De-Multiplexer

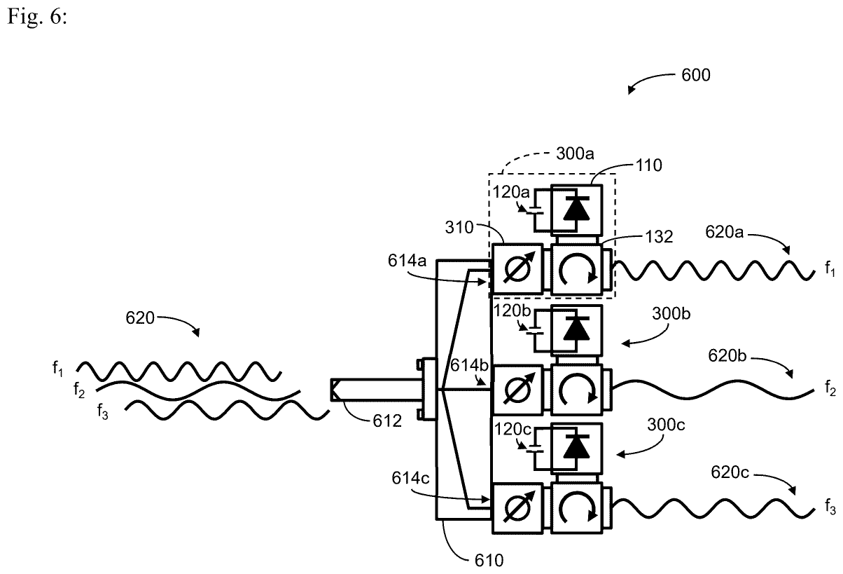

FIG. 6 schematically illustrates an example system 600 (e.g., THz demultiplexing system) comprising a plurality of devices 300 (e.g., tracking oscillators) in accordance with certain implementations described herein. The example system 600 as described herein can be configured to massively increase the number of simultaneous wireless devices 300 to utilize many frequency channels. In such a highly frequency multiplexed scenario, the system 600 can be configured to separate multiple wireless signals from one another. In certain implementations, the system 600 is configured to tune the bandwidth of the devices 300 (e.g., amplifying filters) by controlling the DC bias voltages 120 to change the center frequencies of the devices 300. In certain implementations, the system 600 can comprise a plurality of THz detectors (not shown) each THz detector of the plurality of THz detectors in optical communication with a corresponding device 300 of the plurality of devices 300, the system 600 configured to demultiplex the plurality of THz communication signals to the plurality of THz detectors.

As schematically illustrated in FIG. 6, the example system 600 comprises a waveguide power splitter 610 comprising an input 612 (e.g., a receiver antenna/feedhorn) configured to wirelessly receive a plurality of THz communication signals 620 having different frequencies from one another (e.g., f₁, f₂, f₃). The power splitter 610 further comprises a plurality of outputs 614 (e.g., output ports) and the power splitter 610 is configured to separate and transmit the THz communication signals 620 received at the input 612 to the plurality of outputs 614, each output 614 of the plurality of outputs 614 receiving a corresponding THz communication signal 620 of the plurality of THz communication signals 620. The system 600 further comprises a plurality of devices 300 (e.g., waveguide RTD injection tracking oscillators) as described herein with regard to FIGS. 3A and 3B. Each device 300 of the plurality of devices 300 is in optical communication with a corresponding output 614 of the plurality of outputs 614. For example, as schematically illustrated by FIG. 6, the plurality of THz communication signals 620 comprises three THz communication signals 620a-c, the plurality of devices 300 comprises three devices 300a-c in parallel with one another, each device 300 is in optical communication with a corresponding output 614a-c of the power splitter 610, and the power splitter 610 separates and transmits the plurality of THz communication signals 620 such that each output 614a-c receives a corresponding THz communication signal 620a-c and each device 300a-c receives the corresponding THz communication signal 620a-c.

In certain implementations, as schematically illustrated by FIG. 6, the corresponding bias voltages 120a-c of the plurality of devices 300 can be tuned to be resonant with a predetermined carrier frequency to be filtered such that each device 300a-c emits a corresponding one of the plurality of external THz wireless communication signals 620a-c. The variable attenuators 310 of the plurality of devices 300 can be tuned to ensure sufficiently narrow bandwidths such that only one frequency is filtered. While the devices 300 are shown in FIG. 6 in the reflection geometry, in certain other implementations, one or more of the devices 300 can be in the transmission geometry.

In certain implementations, as schematically illustrated in FIG. 6, the injection nature of the devices 300 (e.g., tracking oscillators) can allow the input wireless signals 620 to be very weak, making a simple power splitter sufficient to separate the input wireless signals 620 into the various devices 300 for subsequent detection (not shown). For example, the devices 300 of FIGS. 3A and 3B can be configured for 10 MHz bandwidth with 40 dB injection amplification which can allow frequency multiplexing of 5000 simultaneous wireless connections in a 50 GHz bandwidth corresponding to the water absorption window ranging from 250 to 300 GHz carrier frequencies.

In certain implementations, the device 300 is a sub-component of the system 600 and provides spectral filtering (e.g., frequency) and gain (e.g., power) due to the injection locking mechanism of the RTD 110. The device 300 can track an input frequency and can output more power than on the input, in a similar manner as the device 100 (e.g., injection locking amplifier) can. Since the power splitter 610 can send all three frequencies to all three output ports, the amplitude going into each device 300 can be reduced. The amplitude can be further reduced by an attenuator to tune the tracking bandwidth (e.g., via the injection locking range). Since the output power of the RTD 110 is agnostic to the input power, amplification can occur recovering the input power losses.

### Example 7: Multiplexed THz Oscillator and Via Photomixing

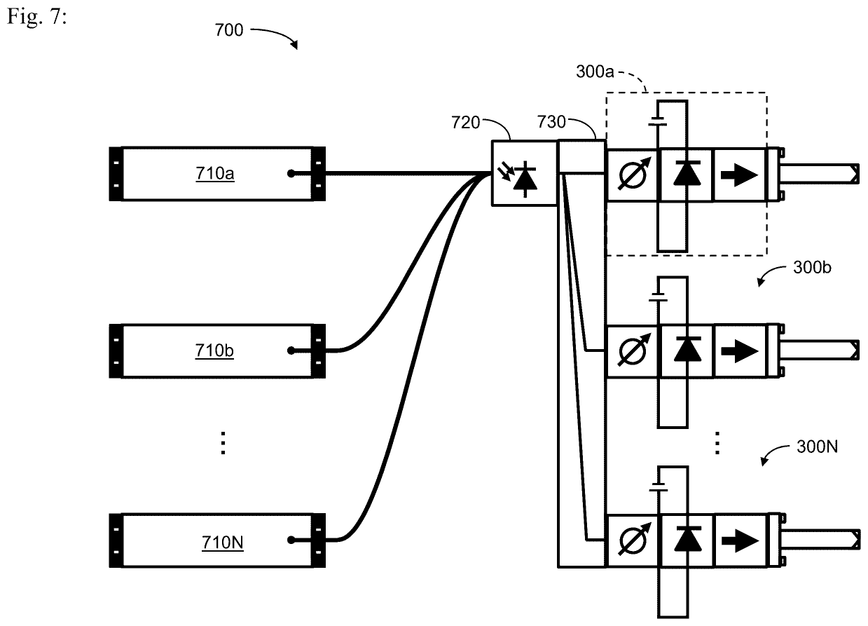

FIG. 7 schematically illustrates an example system 700 configured for coherent detection of THz waves at harmonic frequencies in accordance with certain implementations described herein. The system 700 comprises a plurality of optically carried THz frequency sources 710 (e.g., opto-THz sources 710a, b, . . . , N) operating at a plurality of THz frequencies (e.g., fₐ, f_{b}, . . . , f_{N}) different from one another, each THz frequency source 710 configured to emit optical signals at a corresponding THz frequency.

In certain implementations, the system 700 further comprises an optical combiner (not shown) configured to receive and merge the optical signals from the plurality of THz frequency sources 710. For example, the optical combiner can comprise a multiplexer configured to multiplex the optical signals received from the plurality of THz frequency sources 710 and to generate a plurality of THz waves.

In certain implementations, the system 700 further comprises a waveguide photomixer 720 configured to receive the merged optical signals from the optical combiner and to convert the merged optical signals into a THz radiation signal. As schematically depicted in FIG. 7, the optical signals from the plurality of THz frequency sources 710 can be combined in the optical domain and coupled to the single THz photomixer 720. The THz photomixer 720 can radiate the THz frequencies of every frequency difference between optical lines within its bandwidth.

In certain implementations, the system 700 further comprises a waveguide power splitter 730 comprising an input port in optical communication with an output of the photomixer 720, the power splitter 730 further comprising a plurality of output ports. In certain implementations, the system 700 further comprises a plurality of devices 300 (e.g., waveguide RTD injection tracking oscillators), each device 300 in optical communication with a corresponding output port of the power splitter 730. Each device 300 (e.g., tracking oscillator) can be configured to filter and amplify a predetermined frequency component of the THz radiation from the plurality of THz frequency sources 710. For example, each device 300 can be tuned to a corresponding center frequency and bandwidth by the corresponding DC bias voltage 120 and variable THz attenuator 310 of the device 300.

In certain implementations, the photomixer 720 is configured to split the radiated output power between many THz waves when multiplexed. The amplifying filters of the devices 300 (e.g., waveguide injection THz tracking oscillators) can allow multiplexing to be practical. Additionally, the devices 300 can isolate and/or reject incidental THz waves generated by the photomixing of optical frequencies from the separate THz frequency sources 710. The devices 300 are depicted in FIG. 7 as having transmission injection geometries, while in certain other implementations, one or more of the devices 300 has the reflection geometry.

### Example 8: Multiplexed THz Wireless Communications System

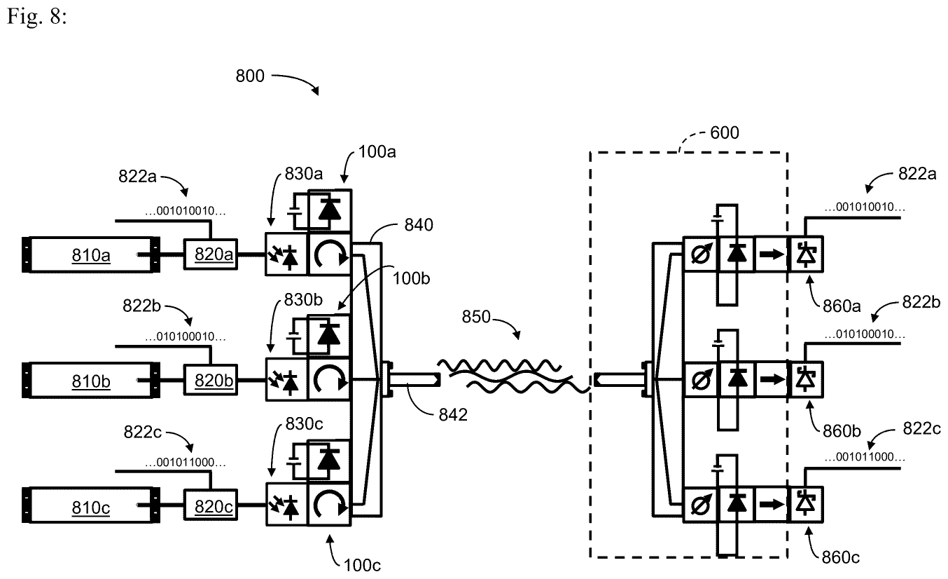

FIG. 8 schematically illustrates an example system 800 (e.g., a frequency multiplexed THz wireless communications system) in accordance with certain implementations described herein. Building on the other devices and systems disclosed herein, the example system 800 can represent one of many possible configurations for a THz wireless communications system. The example system 800 can utilize many of the example devices described herein and can demonstrate a modular nature of the device 100 (e.g., injection waveguide RTD amplifier).

The system 800 comprises a plurality of optically carried THz frequency sources 810 (e.g., opto-THz sources 810a-c) operating at a plurality of THz frequencies (e.g., fₐ, f_{b}, f_{c}) different from one another, the optical signals from each THz frequency source 810 modulated with a corresponding data stream 822a-c (e.g., by modulators 820a-c). For example, the example system 800 of FIG. 8 includes multiple optically carried THz sources 810a-c, each operating at a unique THz frequency. The plurality of THz frequency sources 810 can comprise a plurality of photomixer-based THz generators, each THz generator configured to generate two optical tones beating on a uni-travelling-carrier photodiode. The optical signals from the THz frequency sources 810a-c can be modulated to encode the separate data streams 822a-c.

In certain implementations, the system 800 further comprises a plurality of waveguide photomixers 830, each photomixer 830 of the plurality of waveguide photomixers 830 configured to convert the optical signals from a corresponding THz frequency source 810 of the plurality of THz frequency sources 810 into THz radiation with the corresponding encoded data stream. For example, the photomixers 830 can be used to convert the optically carried THz waves, and encoded information, into THz radiation. The system 800 further comprises a plurality of devices 100, each device 100a-c of the plurality of devices 100 configured to receive the THz radiation from a corresponding photomixer 830 of the plurality of waveguide photomixers 830. The radiation from each photomixer 830 can be amplified by the corresponding device 100a-c (e.g., waveguide RTD injection amplifier) as described herein with regard to FIGS. 1A and 1B. The bias voltage 120 of each device 100a-c can be tuned such that the device 100a-c amplifies at the carrier frequency of the respective optical terahertz operating frequency of the corresponding data channel. While the devices 100 are depicted in FIG. 8 to be in a reflection geometry, in certain other implementations, one or more devices 100 can have the transmission geometry.

In certain implementations, the system 800 further comprises a waveguide power combiner 840 configured to combine the amplified radiation from the plurality of devices 100 and a transmission antenna/feedhorn 842 configured to emit the combined amplified radiation 850. The combined elements of photomixers 830, devices 100 (e.g., injection amplifiers), and power combiner 840 can constitute a THz wireless communications frequency multiplexer.

The combined amplified radiation 850 from the transmission feedhorn/antenna 842 can propagate through free-space (e.g., a multiplexed wireless link) to a receiver feedhorn/antenna 610 of a system 600 (e.g., a THz wireless communication frequency de-multiplexer), as described herein. The separated frequency channels can be connected to individual THz detectors 860, which can read out the corresponding data stream 822a-c carried on the respective THz waves. The total implementation of the system 800 can constitute a frequency multiplexed THz wireless communications network. The wireless link 850 of the system 800 can operate within a 250 GHz to 350 GHz atmospheric transmission window.

### Example 9: Waveguide RTD Injection and Absolute Phase Noise Characterization Method

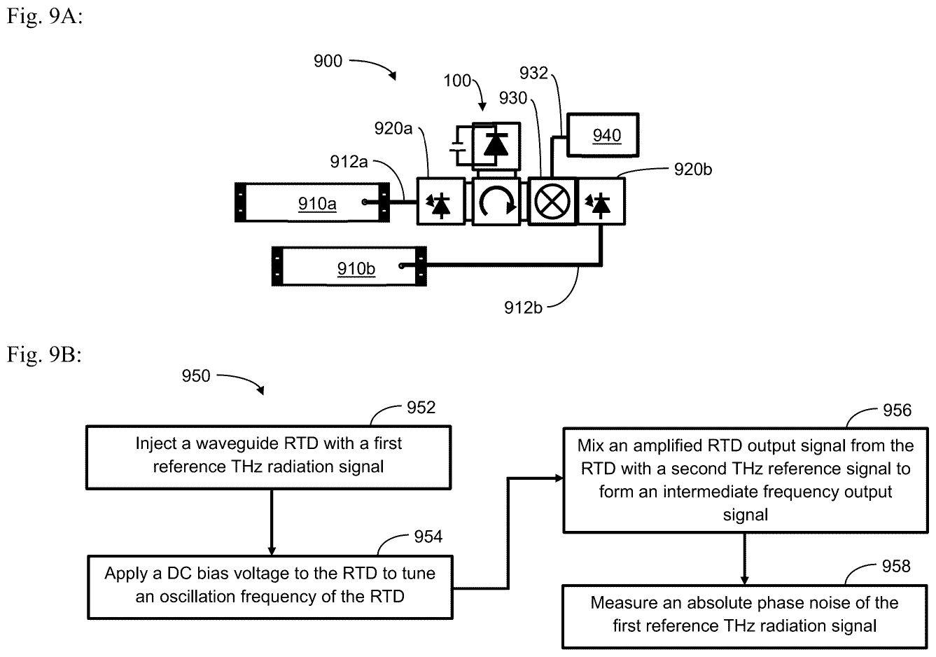

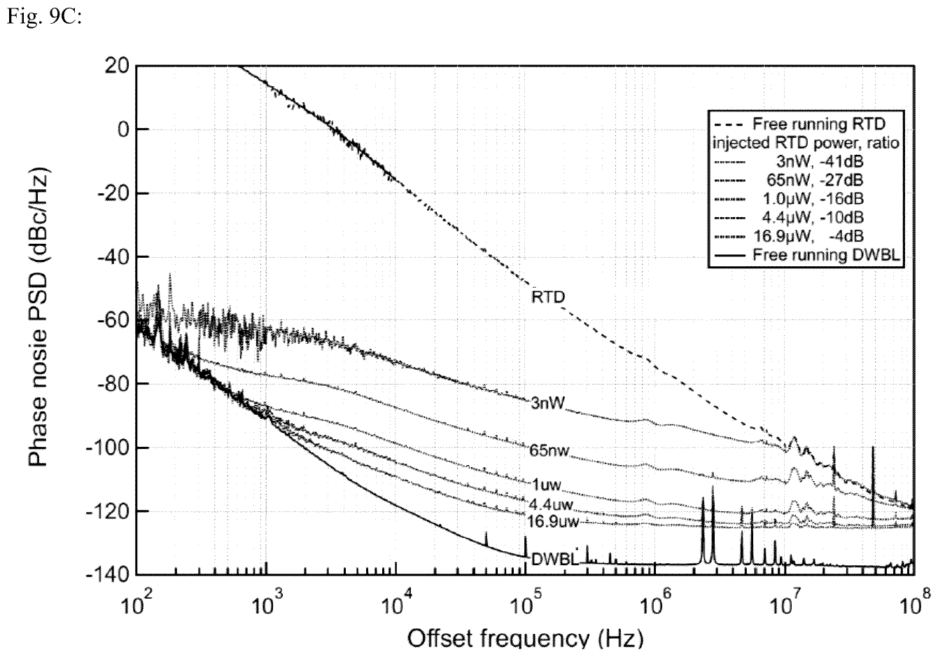

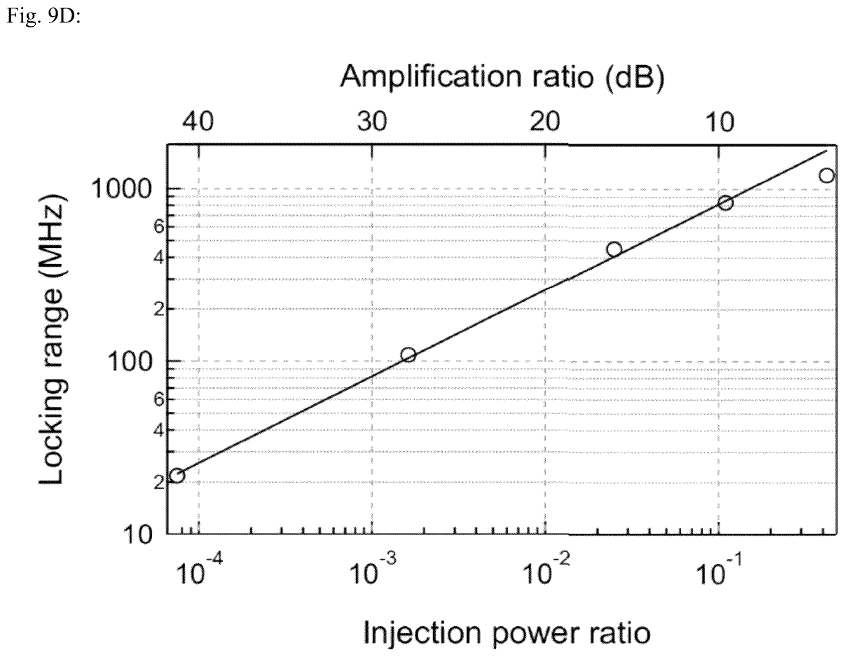

FIG. 9A schematically illustrates an example system 900 (e.g., utilizing absolute injection PN) in accordance with certain implementations described herein. The example system 900 comprises first and second optically carried THz frequency sources 910a, b (e.g., opto-THz sources) operating at first and second THz frequencies (e.g., fₐ, f_{b}), respectively, the first and second THz frequencies different from one another. The system 900 further comprises first and second waveguide photomixers 920a, b, the first photomixer 920a configured to receive and convert first optical signals 912a from the first THz frequency source 910a into first THz radiation and the second photomixer 920b configured to receive and convert second optical signals 912b from the second THz frequency source 910b into second THz radiation. The system 900 further comprises a device 100, 200 comprising a waveguide RTD 110, the device 100,200 configured to receive the first THz radiation 912a and to output an amplified THz radiation. The system 900 further comprises a mixer 930 (e.g., mixer 510) configured to receive the amplified THz radiation and the second THz radiation and to emit an intermediate frequency (IF) output signal 932 in response to a mixture of the amplified THz radiation and the second THz radiation. The system 900 further comprises a phase noise analyzer 940 configured to receive the IF output signal 932 and to generate information regarding a phase noise of the amplified THz radiation from the device 100, 200.

In certain implementations, the example system 900 performs a method 950 for injection locking the waveguide RTD 110 and characterizing the absolute phase noise of the amplified THz radiation in accordance with certain implementations described herein. The process of injection amplification is not the same as broadband amplification. As a result, residual noise can be imparted from the RTD 110 on the amplified THz radiation.

FIG. 9B is a flow diagram of an example method 950 in accordance with certain implementations described herein. In an operational block 952, the method 950 comprises injecting a waveguide RTD 110 with a first reference THz radiation signal. For example, the first optically carried THz frequency source 910a can be in optical communication with the first photomixer 920a which can produce the first reference THz radiation signal. The RTD injection can lock to the first optically carried THz frequency source 910a.

In an operational block 954, the method 950 further comprises applying a DC bias voltage 112 to the RTD 110 to tune an oscillation frequency of the RTD 110 and to establish injection locking with the first reference THz radiation signal. For example, the first photomixer 920a can inject the waveguide RTD 110 with the first reference THz radiation signal (e.g., in the same way as described with regard to the example device 100 and FIG. 1A). The DC bias voltage 112 of the waveguide RTD 110 can be tuned to match the RTD frequency with the frequency of the first THz radiation generated by the first photomixer 920a.

In an operational block 956, the method 950 further comprises mixing an amplified RTD output signal (e.g., amplified THz radiation) from the RTD 110 with the second THz reference signal to form an intermediate frequency (IF) output signal in response to a mixture of the amplified RTD output signal and the second THz reference signal. For example, the amplified THz radiation outputted from the device 100 can be inputted to the RF input of the mixer 930 (e.g., THz waveguide mixer) and the second THz radiation from the second photomixer 920b can be inputted to an LO input of the mixer 930. The second THz radiation can be generated by the second photomixer 920b which is driven by the second optically carried THz frequency source 910b that is frequency shifted from the first optically carried THz frequency source 910a.

In an operational block 958, the method 950 further comprises measuring an absolute phase noise of the first reference THz radiation signal. For example, mixing the amplified RTD output signal with the second THz reference signal can be performed using the mixer 930 and measuring the absolute phase noise of the first reference THz radiation signal can comprise inputting the IF output signal 932 from the mixer 930 to the phase noise analyzer 940. The phase noise analyzer 940 can include a dual-channel heterodyne detection system for cross-correlation.

In certain implementations, the resulting phase noise measured by the phase noise analyzer 940 can be the combination of the relative phase noise of the two optically carried terahertz sources 910a, b and residual phase noise of the injection process. When the two optically carried terahertz sources 910a, b have comparable phase noise with one another, the absolute phase noise of injected THz wave can be accurately measured by the phase noise analyzer 940.

This example method 900 can be broadly applied to other THz oscillator sources, not just photomixed sources. The reference oscillator (e.g., the second source 910b) can have similar or lower phase noise than the injecting oscillator (e.g., the first source 910a). Furthermore, the geometry of THz injection can be either transmission or reflection, even though only reflection geometry is shown in FIG. 9A.

FIG. 9C is a plot of the phase noise power spectral densities (PSD) for a free running RTD (top trace), a dual wavelength Brillouin laser (DWBL) (bottom trace), and injected RTD and several injection powers for an example system 900 in accordance with FIG. 9A. While injection reduces the phase noise of the free running RTD, it does not perfectly follow the DWBL source. The resulting phase noise is the residual injection noise that reduces with injection power and offset frequency.

FIG. 9D is a plot of the variation of RTD injection locking frequency range with injection power ratio for an example system 900 in accordance with FIG. 9A. The inverse of the injection power ratio is the amplification ratio in logarithmic units. The open circles are locking range data ascertained from the phase noise measurements. The solid line is a fit to the data excluding the largest injection power ratio.

### Example 10: Waveguide RTD Injection and Residual Phase Noise Characterization Method

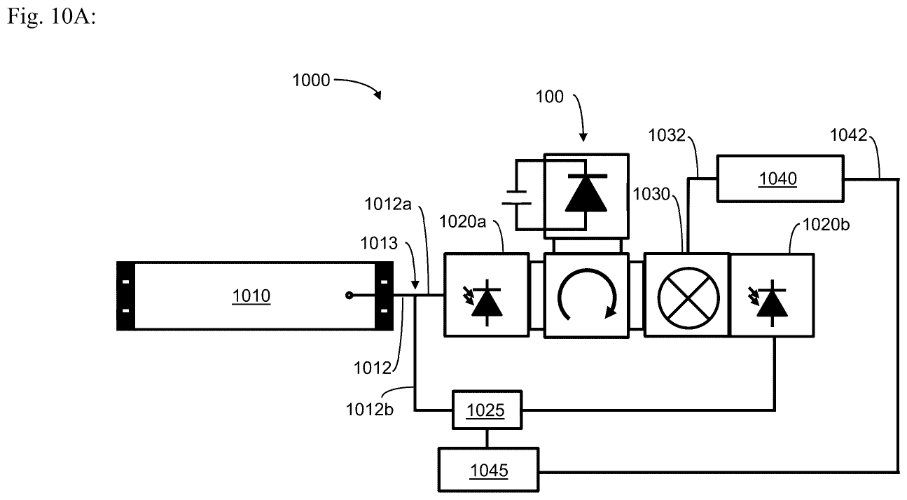

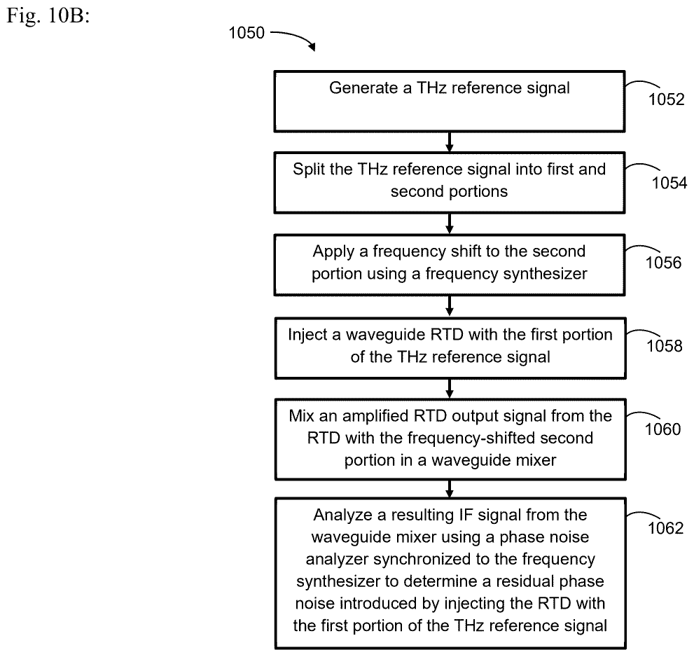

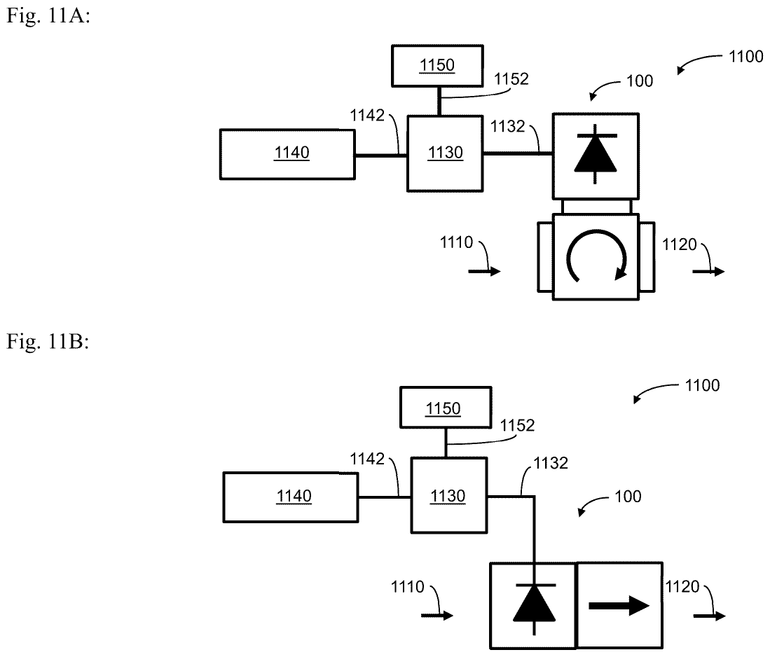

FIG. 10A is a schematic of an example system 1000 (e.g., utilizing residual injection PN) in accordance with certain implementations described herein. The example system 1000 comprises an optically carried THz frequency source 1010 (e.g., opto-THz source) operating at a THz frequency and configured to generate optical signals 1012 at the THz frequency. The example system 1000 further comprises an optical splitter 1013 configured to receive and split the optical signals 1012 from the THz frequency source 1010 into a first portion 1012a and a second portion 1012b. The system 1000 further comprises first and second waveguide photomixers 1020a,b, the first photomixer 1020a configured to receive and convert the first portion 1012a of the optical signals 1012 from the THz frequency source 1010 into first THz radiation. The system 1000 further comprises a frequency shifter 1025 configured to receive the second portion 1012b of the optical signals 1012 from the THz frequency source 1010, to frequency shift the second portion 1012b, and to transmit the frequency-shifted second portion 1012b to the second photomixer 1020b, which is configured to receive and convert the frequency-shifted second portion 1012b into second THz radiation.

The system 1000 further comprises a device 100,200 comprising a waveguide RTD 110, the device 100,200 configured to receive the first THz radiation and to output an amplified THz radiation. The system 1000 further comprises a mixer 1030 (e.g., mixer 510) configured to receive the amplified THz radiation and the second THz radiation and to emit an intermediate frequency (IF) output signal 1032 (e.g., data under test or DUT) in response to a mixture of the amplified THz radiation and the second THz radiation. The system 1000 further comprises a phase noise analyzer 1040 configured to receive the IF output signal 1032 and to generate a reference signal 1042 indicative of a residual phase noise of the amplified THz radiation from the device 100,200. The system 1000 further comprises a synthesizer 1045 configured to receive the reference signal 1042 and to transmit a control signal to the frequency shifter 1025.

In certain implementations, the example system 1000 performs a method 1050 for injection locking the waveguide RTD 110 and characterizing residual phase noise of the waveguide RTD 110 in accordance with certain implementations described herein. The process of injection amplification is not the same as broadband amplification. As a result, residual noise can be imparted from the RTD 110 on the amplified THz radiation signal.

FIG. 10B is a flow diagram of an example method 1050 in accordance with certain implementations described herein. In an operational block 1052, the method 1050 comprises generating a THz reference signal 1012. In an operational block 1054, the method 1050 further comprises splitting the THz reference signal into a first portion 1012a and a second portion 1012b. In an operational block 1056, the method 1050 further comprises applying a frequency shift to the second portion 1012b using the frequency synthesizer 1045 (e.g., using the frequency shifter 1025 and the frequency synthesizer 1045). The frequency shifter 1045 can comprise a direct digital synthesizer (DDS) driven by a microwave clock.

In an operational block 1058, the method 1050 further comprises injecting a waveguide RTD 110 with the unshifted first portion 1012a of the THz reference signal 1012. For example, the optically carried THz frequency source 1010 can be in optical communication with the first photomixer 1020a which can produce the THz radiation that injects the waveguide RTD 110 (e.g., in the same way as described herein with regard to the example device 100 and FIG. 1A).

In an operational block 1060, the method 1050 further comprises mixing an amplified RTD output signal from the waveguide RTD 110 with the frequency-shifted second portion 1012b in the THz waveguide mixer 1030. The LO input of the THz waveguide mixer 1030 can connect to the second THz photomixer 1020b which can be driven by the frequency-shifted second portion 1012b.

In an operational block 1062, the method 1050 further comprises analyzing a resulting IF signal 1032 from the mixer 1030 using a phase noise analyzer 1040 synchronized to the frequency synthesizer 1045 to determine a residual phase noise introduced by injecting the waveguide RTD 110 with the unshifted first portion of the THz reference signal. For example, the phase noise analyzer 1040 can be referenced to the same optical THz frequency source 1010 that drives the optically carried THz frequency shifter 1025. The DC bias voltage 112 of the waveguide RTD 110 can be tuned to match the RTD frequency with the input THz radiation frequency generated by the first photomixer 1020a. The RTD injection can lock to the optical THz frequency source 1010. The resulting phase noise measured by the phase noise analyzer 1040 can be the residual phase noise of the injection process.

This example method can be broadly applied to other THz oscillator sources, not just photomixed. Furthermore, the geometry of THz injection can be either transmission or reflection, even though only reflection is shown in FIG. 10.

### Example 11: Waveguide RTD Injection and High-Speed Phase Modulation

FIGS. 11A and 11B schematically illustrate an example device 1100 (e.g., a high-speed, voltage-controlled phase modulator) in accordance with certain implementations described herein. The device 1100 comprises a device 100 comprising a waveguide RTD 110 (e.g., as described herein with regard to FIGS. 1A and 1B), the device 100 configured to receive an input signal 1110 and to emit an output signal 1120. The device 1100 further comprises a bias-T 1130 configured to receive a modulation signal 1142 from an arbitrary modulation source 1140 and a DC signal 1152 from an independent DC power supply 1150 and to emit an AC bias voltage 1132 and to transmit the AC bias voltage 1132 to the RTD 110.

When a source injects an RTD 110 (regardless of injection geometry), phase locking between the source and RTD radiation occurs. The phase difference between the source and the RTD radiation can be controlled by adjusting the bias voltage 1132 of the RTD 110. A phase difference (e.g., up to ±π/2) can be created while injection locked. Thus, fast modulation of the RTD bias voltage 1132 can generate fast modulation of the output phase of the RTD radiation. A large modulation depth (e.g., up to π radians) can be achieved without breaking the injection lock. The modulation bandwidth can be limited by the RTD response, which electrically is equal to the radiation frequency (e.g., greater than 100 GHz). The realized phase modulator can be agnostic of the injection source and thus can be universal. FIGS. 11A and 11B schematically illustrate the device 1100 (e.g., injection phase modulator) in reflection and transmission geometry, respectively. The bias T 1130 can be used to provide the bias voltage 1132 to the RTD 110. The DC power supply 1150 provides slow control over the RTD bias voltage 1132 to maintain injection locking and to tune the overall phase shift between source and RTD radiation at the output 1120. The modulation source 1140 can be coupled to the RTD 110 via an RF port of the bias T 1130, and the modulation signal 1142 can provide the modulation that is written to the RTD radiation.

### Example 12: Waveguide RTD Injection and High-Speed Intensity Modulation

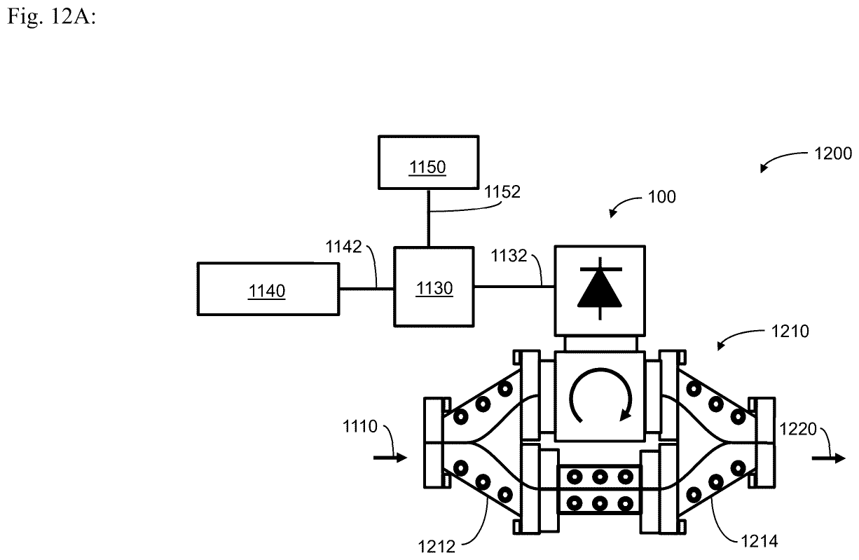

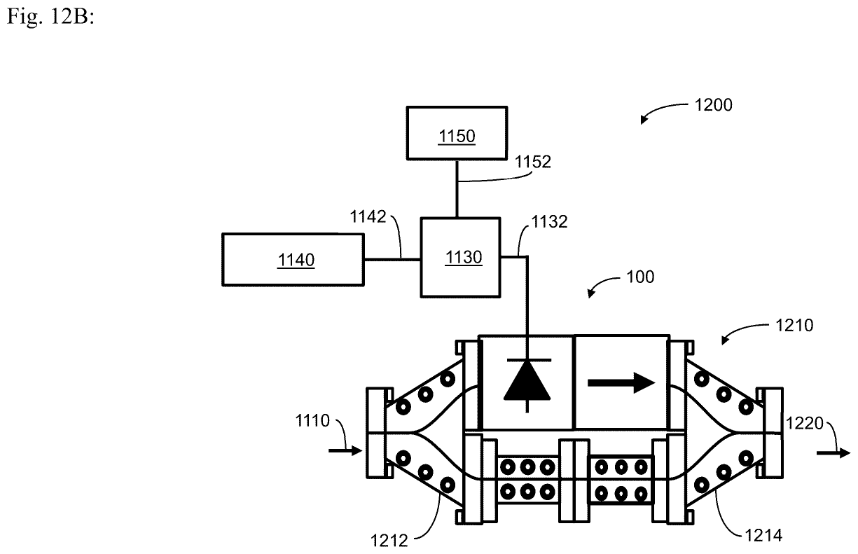

FIGS. 12A and 12B schematically illustrate an example device 1200 (e.g., a high-speed, voltage-controlled intensity modulator) in accordance with certain implementations described herein. The device 1200 comprises the device 1100 placed in one arm of a Mach-Zehnder interferometer 1210. The interferometer 1210 comprises a waveguide power splitter 1212 (e.g., 50:50) configured to receive and split the input signal 1110, with a first portion of the input signal 1110 propagating through a first arm of the interferometer 1210 and acquiring a phase shift by the device 1100, and a second portion of the input 1110 propagating through a second arm of the interferometer 1210 not acquiring a phase shift. The interferometer 1210 further comprises a 50:50 power combiner 1214 configured to recombine the first and second portions to produce an output signal 1220. At recombination, the first and second portions interfere, producing an amplitude modulation of the original input 1110. The amplitude modulation is written to the RTD 110 via the modulation signal 1142 from the modulation source 1140, and the bias voltage 1132 from the bias T 1130 is provided to the RTD 110. The DC voltage 1152 from the DC power supply 1150 maintains injection and a phase difference for amplitude modulation of the output 1220 to occur. The realized intensity modulator can be as universal, in terms of source compatibility, and high-speed, in terms of bandwidth, as the realized phase modulator of FIGS. 11A and 11B. FIGS. 12A and 12B show the device 1200 (e.g., injection intensity modulator) in reflection and transmission geometry, respectively.

Example, non-limiting experimental data are included herein to illustrate results achievable by various implementations of the systems and methods described herein. All ranges of data and all values within such ranges of data that are shown in the figures or described in the specification are expressly included in this disclosure. The example experiments, experimental data, tables, graphs, plots, figures, and processing and/or operating parameters (e.g., values and/or ranges) described herein are intended to be illustrative of operating conditions of the disclosed systems and methods and are not intended to limit the scope of the operating conditions for various implementations of the methods and systems disclosed herein. Additionally, the experiments, experimental data, calculated data, tables, graphs, plots, figures, and other data disclosed herein demonstrate various regimes in which implementations of the disclosed systems and methods may operate effectively to produce one or more desired results. Such operating regimes and desired results are not limited solely to specific values of operating parameters, conditions, or results shown, for example, in a table, graph, plot, or figure, but also include suitable ranges including or spanning these specific values. Accordingly, the values disclosed herein include the range of values between any of the values listed or shown in the tables, graphs, plots, figures, etc. Additionally, the values disclosed herein include the range of values above or below any of the values listed or shown in the tables, graphs, plots, figures, etc. as might be demonstrated by other values listed or shown in the tables, graphs, plots, figures, etc. Also, although the data disclosed herein may establish one or more effective operating ranges and/or one or more desired results for certain implementations, it is to be understood that not every implementation need be operable in each such operating range or need produce each such desired result. Further, other implementations of the disclosed systems and methods may operate in other operating regimes and/or produce other results than shown and described with reference to the example experiments, experimental data, tables, graphs, plots, figures, and other data herein.

The invention has been described in several non-limiting implementations. It is to be understood that the implementations are not mutually exclusive, and elements described in connection with one implementation may be combined with, rearranged, or eliminated from, other implementations in suitable ways to accomplish desired design objectives. No single feature or group of features is necessary or required for each implementation. Various modifications and applications may occur to those skilled in the art without departing from the true spirit and scope of the invention. Thus, for example, in any method or process disclosed herein, the acts or operations making up the method/process may be performed in any suitable sequence and are not necessarily limited to any particular disclosed sequence. Features or elements from various implementations and examples discussed above may be combined with one another to produce alternative configurations compatible with implementations disclosed herein.

For purposes of summarizing the present invention, certain aspects, advantages and novel features of the present invention are described herein. It is to be understood, however, that not necessarily all such advantages may be achieved in accordance with any particular implementation. Thus, the present invention may be embodied or carried out in a manner that achieves one or more advantages without necessarily achieving other advantages as may be taught or suggested herein.

As used herein any reference to “one implementation” or “some implementations” or “an implementation” or “certain implementations” means that a particular element, feature, structure, or characteristic described in connection with the implementation is included in at least one implementation. The appearances of the phrase “in one implementation” or “in certain implementations” in various places in the specification are not necessarily all referring to the same implementation. Conditional language used herein, such as, among others, “can,” “could,” “might,” “may,” “e.g.,” and the like, unless specifically stated otherwise, or otherwise understood within the context as used, is generally intended to convey that certain implementation include, while other implementations do not include, certain features, elements and/or steps. In addition, the articles “a” or “an” or “the” as used in this application and the appended claims are to be construed to mean “one or more” or “at least one” unless specified otherwise.

As used herein, the terms “comprises,” “comprising,” “includes,” “including,” “has,” “having” or any other variation thereof, are open-ended terms and intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), or both A and B are true (or present). As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain implementations require at least one of X, at least one of Y, and at least one of Z to each be present.

Language of degree, as used herein, such as the terms “approximately,” “about,” “generally,” and “substantially,” represent a value, amount, or characteristic close to the stated value, amount, or characteristic that still performs a desired function or achieves a desired result. For example, the terms “approximately,” “about,” “generally,” and “substantially” may refer to an amount that is within ±10% of, within ±5% of, within ±2% of, within ±1% of, or within ±0.1% of the stated amount. The ranges disclosed herein also encompass any and all overlap, sub-ranges, and combinations thereof. Language such as “up to,” “at least,” “greater than,” less than,” “between,” and the like includes the number recited. As used herein, the meaning of “a,” “an,” and “said” includes plural reference unless the context clearly dictates otherwise. While the structures and/or methods are discussed herein in terms of elements labeled by ordinal adjectives (e.g., first, second, etc.), the ordinal adjectives are used merely as labels to distinguish one element from another, and the ordinal adjectives are not used to denote an order of these elements or of their use.

Thus, while only certain implementations have been specifically described herein, it will be apparent that numerous modifications may be made thereto without departing from the spirit and scope of the invention. Further, acronyms are used merely to enhance the readability of the specification and claims. It should be noted that these acronyms are not intended to lessen the generality of the terms used and they should not be construed to restrict the scope of the claims to the implementations described therein.

What is claimed is:

1. A device comprising:
a waveguide resonant tunneling diode (RTD) configured to oscillate at a terahertz (THz) frequency;
a DC power supply electrically coupled to the RTD and configured to provide a DC bias voltage to the RTD; and
a waveguide isolating element operatively connected to the RTD;
wherein the RTD, when injection-locked to an external incident radiation signal having a first frequency, generates and emits an output radiation signal having a second frequency.

2. The device of claim 1, wherein the RTD is configured to operate within a frequency range of 100 GHz to 1 THz.

3. The device of claim 1, wherein the waveguide isolating element is a three-port circulator comprising an injection port configured to receive the external incident radiation signal and an output port configured to direct the output radiation signal away from the injection port.

4. The device of claim 1, wherein the waveguide isolating element is an optical isolator comprising an input port configured to receive a radiation signal from the RTD and an output port configured to emit the output radiation signal.

5. The device of claim 1, wherein the RTD is mounted in a waveguide package configured to maximize power extraction efficiency.

6. The device of claim 1, wherein the DC bias voltage is configured to be adjusted to tune an oscillation frequency of the RTD, the RTD is configured to prevent undesired feedback and to maintain injection locking stability, and the output radiation signal is amplified compared to the external incident radiation signal.

7. The device of claim 1, wherein the DC bias voltage is configured to be adjusted such that the RTD oscillates at an integer multiple of the first frequency, thereby generating a harmonic frequency signal of the external incident radiation signal.

8. The device of claim 7, wherein the DC bias voltage is tuned for the RTD to generate a second harmonic signal of the external incident radiation signal.

9. The device of claim 7, wherein the RTD is mounted in a waveguide package, the package comprising an input port and an output port, the input port having a waveguide dimension larger than that of the output port, the package configured to accommodate a higher input frequency and to facilitate harmonic locking.

10. The device of claim 1, further comprising:
a variable power attenuator operatively coupled to the RTD and configured to control an amplitude of the external incident radiation signal,
wherein a tracking bandwidth of the RTD is determined by a ratio of input power of the external incident radiation signal to an oscillation power of the RTD, enabling frequency tracking within an injection locking frequency range.

11. A wireless communication system comprising:
a THz radiation source;
a THz radiation detector;
the device of claim 1;
a first wireless link between the THz radiation source and the device; and
a second wireless link between the device and the THz radiation detector, wherein the RTD is configured to receive, amplify, and retransmit a THz signal from the THz radiation source and to function as a THz repeater configured to extend a communication range of the system.

12. A device comprising:
the device of claim 1; and
a waveguide mixer configured to receive and process a subharmonic multiple of the incident radiation signal.

13. A system comprising:
a waveguide power splitter comprising:
an input configured to wirelessly receive a plurality of THz communication signals having different frequencies from one another; and
a plurality of outputs, the waveguide power splitter configured to separate and transmit the THz communication signals received at the input to the plurality of outputs, each output of the plurality of outputs receiving a corresponding THz communication signal of the plurality of THz communication signals; and
a plurality of devices as defined in claim 3, each device of the plurality of devices in optical communication with a corresponding output of the plurality of outputs and configured to track and amplify a respective THz frequency channel.

14. The system of claim 13, further comprising a plurality of THz detectors, each THz detector of the plurality of THz detectors in optical communication with a corresponding device of the plurality of devices, the system configured to demultiplex the plurality of THz communication signals to the plurality of THz detectors.

15. A system comprising:
a plurality of THz frequency sources operating at a plurality of THz frequencies different from one another, each THz frequency source of the plurality of THz frequency sources configured to emit optical signals at a corresponding THz frequency;
an optical combiner configured to receive and merge the optical signals from the plurality of THz frequency sources;
a waveguide photomixer configured to receive the merged optical signals and to convert the merged optical signals into a THz radiation signal;
a waveguide power splitter comprising an input port in optical communication with an output of the photomixer, the power splitter further comprising a plurality of output ports; and
a plurality of devices as defined in claim 3, each device of the plurality of devices in optical communication with a corresponding output port of the power splitter and configured to filter and amplify a predetermined frequency component of the THz radiation from the plurality of THz frequency sources.

16. A system comprising:
a plurality of THz frequency sources operating at a plurality of THz frequencies different from one another, optical signals from each THz frequency source of the plurality of THz frequency sources modulated with a corresponding data stream;
a plurality of waveguide photomixers, each photomixer of the plurality of waveguide photomixers configured to convert the optical signals from a corresponding THz frequency source of the plurality of THz frequency sources into THz radiation with the corresponding encoded data stream; and
a plurality of devices as described in claim 1, wherein each device of the plurality of devices is tuned to amplify at a corresponding carrier frequency of a corresponding data channel.

17. The system of claim 16, wherein the plurality of THz frequency sources comprises a plurality of photomixer-based THz generators, each THz generator configured to generate two optical tones beating on a uni-travelling-carrier photodiode.

18. The system of claim 16, further comprising a wireless link operating within a 250 GHz to 350 GHz atmospheric transmission window.

19. A method for injection locking a waveguide RTD and characterizing absolute phase noise of the resulting THz radiation, the method comprising:
injecting a waveguide RTD with a first reference THz radiation signal;
applying a DC bias voltage to the RTD to tune an oscillation frequency of the RTD and to establish injection locking with the first reference THz signal;
mixing an amplified RTD output signal from the RTD with a second THz reference signal to form an intermediate frequency (IF) output signal in response to a mixture of the amplified RTD output signal and the second THz reference signal; and
measuring an absolute phase noise of the first reference THz radiation signal.

20. The method of claim 19, wherein mixing the amplified RTD output signal with the second THz reference signal is performed using a mixer and measuring the absolute phase noise of the first reference THz radiation signal comprises inputting the IF output signal from the mixer to a phase noise analyzer.

21. The method of claim 20, wherein the phase noise analyzer includes a dual-channel heterodyne detection system for cross-correlation.

22. A method for injection locking a waveguide RTD and characterizing residual phase noise of the waveguide RTD, the method comprising:
generating a THz reference signal;
splitting the THz reference signal into a first portion and a second portion;
applying a frequency shift to the second portion using a frequency synthesizer;
injecting a waveguide RTD with the first portion of the THz reference signal;
mixing an amplified RTD output signal from the waveguide RTD with the frequency-shifted second portion in a waveguide mixer; and
analyzing a resulting IF signal from the waveguide mixer using a phase noise analyzer synchronized to the frequency synthesizer to determine a residual phase noise introduced by injecting the waveguide RTD with the first portion of the THz reference signal.

23. The method of claim 22, wherein said applying a frequency shift comprises using a frequency synthesizer.

24. The method of claim 23, wherein the frequency synthesizer is a direct digital synthesizer (DDS) driven by a microwave clock.

25. A device comprising:
the device of claim 1 configured to receive an input signal and to emit an output signal; and
a bias-T configured to receive a modulation signal from a modulation source and a DC signal from a DC power supply and to emit a bias voltage and to transmit an AC bias voltage to the RTD of the device, wherein the AC bias voltage produces a phase modulation on the output signal.

26. A device comprising:
the device of claim 25; and
a Mach-Zehnder interferometer having a first arm and a second arm, the device of claim 25 nested inside the first arm, the interferometer comprising:
a waveguide power splitter configured to receive and split the input signal into a first portion and a second portion, the first portion propagating through the first arm and acquiring a phase shift, the second portion propagating through the second arm and not acquiring a phase shift; and
a waveguide power combiner configured to recombine the first and second portions to produce an output signal.
